(19) United States
(12) Patent Application Publication
(10) Pub. No.: US 2025/0226184 A1
(43) Pub. Date: Jul. 10, 2025

(54) APPARATUS AND METHOD FOR MODULATING IONS AND RADICAL SPECIES IN PLASMAS

(71) Applicant: Applied Materials, Inc., Santa Clara, CA (US)

(72) Inventors: THAI CHENG CHUA, Cupertino, CA (US); ADAM FISCHBACH, Campbell, CA (US)

(21) Appl. No.: 18/405,726

(22) Filed: Jan. 5, 2024

(51) Int. Cl. H01J 37/32; H01L 21/311

(52) U.S. Cl. CPC H01J 37/32422; H01L 21/31116; H01J 37/32192; H01J 2237/334

(57) ABSTRACT

Embodiments disclosed herein include an apparatus for ion blocking. In an embodiment, the apparatus comprises a first plate, with a plurality of first holes pass through a thickness of the first plate, and a second plate over the first plate, with a plurality of second holes that pass through a thickness of the second plate. In an embodiment, a spacer is provided between the first plate and the second plate.

### BACKGROUND

### 1) Field

Embodiments relate to the field of semiconductor manufacturing and, in particular, apparatuses and methods for modulating ions and radical species in plasmas.

### 2) Description of Related Art

Integrated circuits are made possible by processes which produce intricately patterned material layers on substrate surfaces. Producing patterned material on a substrate requires controlled methods for removal of exposed material. Chemical etching is used for a variety of purposes, including transferring a pattern in photoresist into underlying layers, thinning layers, or thinning lateral dimensions of features already present on the surface. Often, it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Some etch processes are characterized as being a “dry” process. Dry processes typically include a plasma that is used to ionize gasses that are fed into the chamber. The rate that ions travel from the plasma to the surface of the substrate may be at least partially responsible for the etch rate of a given process. Accordingly, the ability to control the flow of ions is desirable for providing precise control of dry etch processes.

### SUMMARY

Embodiments disclosed herein include an apparatus for ion blocking. In an embodiment, the apparatus comprises a first plate, with a plurality of first holes pass through a thickness of the first plate, and a second plate over the first plate, with a plurality of second holes that pass through a thickness of the second plate. In an embodiment, a spacer is provided between the first plate and the second plate.

Embodiments further include a method for plasma etching that comprises generating a plasma in a chamber. In an embodiment, the chamber comprises an ion blocking system between a lid of the chamber and a substrate. In an embodiment, the method further comprises orienting the ion blocking system in a first configuration to allow a first flow rate of ions from the plasma to pass through the ion blocking system and reach the substrate, and orienting the ion blocking system in a second configuration to allow a second flow rate of ions from the plasma to pass through the ion blocking system and reach the substrate.

Embodiments further include a tool that comprises a chamber, and a plasma source coupled to the chamber. In an embodiment, a pedestal is provided in the tool for supporting a substrate in the chamber. In an embodiment, an ion blocking system is provided between the pedestal and the plasma source. In an embodiment, the ion blocking system comprises a first plate with a plurality of first holes that pass through a thickness of the first plate, and a second plate over the first plate with a plurality of second holes that pass through a thickness of the second plate.

### BRIEF DESCRIPTION OF THE DRAWINGS

FIG. 1 is a section view illustration of an ion blocking system that includes a first plate over a second plate, in accordance with an embodiment.

FIG. 2A is a cross-sectional illustration of a portion of an ion blocking system in a configuration that allows for 100% overlap of holes in the first plate and the second plate, in accordance with an embodiment.

FIG. 2B is a cross-sectional illustration of a portion of an ion blocking system in a configuration that allows for partial overlap of holes in the first plate and the second plate, in accordance with an embodiment.

FIG. 2C is a cross-sectional illustration of a portion of an ion blocking system in a configuration that allows for no overlap of holes in the first plate and the second plate, in accordance with an embodiment.

FIG. 3A is a cross-sectional illustration of a portion of an ion blocking system with actuators coupled to the first plate and the second plate, in accordance with an embodiment.

FIG. 3B is a cross-sectional illustration of a portion of an ion blocking system with a first actuator coupled to the first plate to provide lateral displacement and a second actuator coupled to the second plate to provide vertical displacement, in accordance with an embodiment.

FIG. 4 is a cross-sectional illustration of a portion of an ion blocking system with a first plate with first holes and a second plate with second holes that include a diameter that is different than a diameter of the first holes, in accordance with an embodiment.

FIG. 5A is a cross-sectional illustration of a portion of an ion blocking system with a first plate and a second plate that are both electrically grounded, in accordance with an embodiment.

FIG. 5B is a cross-sectional illustration of a portion of an ion blocking system with a first plate and a second plate that are electrically grounded, in accordance with an embodiment.

FIG. 5C is a cross-sectional illustration of a portion of an ion blocking system with a first plate held at a first voltage and a second plate held at a second voltage, in accordance with an embodiment.

FIG. 6A is a plan view illustration of a plate with slot-shaped holes, in accordance with an embodiment.

FIG. 6B is a plan view illustration of a plate with ring-shaped holes, in accordance with an embodiment.

FIG. 7 is a cross-sectional illustration of a microwave plasma system that includes an ion blocking system, in accordance with an embodiment.

FIG. 8A is a cross-sectional illustration of a three-dimensional (3D) NAND structure at a stage of manufacture, in accordance with an embodiment.

FIG. 8B is a cross-sectional illustration of the 3D-NAND structure at a subsequent stage of manufacture, in accordance with an embodiment.

FIG. 9 is a process flow diagram of a process for controlling an ion flow rate with an ion blocking system, in accordance with an embodiment.

FIG. 10 illustrates a block diagram of an exemplary computer system that may be used in conjunction with a processing tool, in accordance with an embodiment.

### DETAILED DESCRIPTION

Systems described herein include systems for modulating the flow rate of ions from a plasma to a substrate below an ion blocking system. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, the control of ions flowing to the surface of the substrate is useful for controlling etching parameters of a given etch process. Ion blocking systems have been used to control the flow of ions. In one instance, a thin plate with small holes is provided. In an alternative approach, small holes are used in conjunction with a thicker plate. Typically, the diameter of holes for these types of ion blocking systems are 1.0 mm or smaller, 500 μm or smaller, or 100 μm or smaller. In both designs, the goal is to maximize the probability of the ions coming into contact with the surface of the plates. Upon contact with the surfaces, the ions will lose their charge and become neutralized. This neutralizes the ions before they reach the underlying substrate.

Further, the plasma density generally scales with the frequency of the plasma. In the case of low to moderate frequencies (e.g., less than approximately 160 MHz) the plasma density is not sufficiently large, and the small diameter holes are able to accommodate the transfer of sufficient amounts of the plasma through the ion blocking system. However, as the plasma density increases, the small holes of the ion blocking system become a choke point and limit the effectiveness of high density plasmas.

Accordingly, embodiments disclosed herein include an ion blocking system that can control ion flow rates, while still allowing for the use of high density plasmas. The high density plasmas are accommodated by providing an ion blocking system that comprises a pair of plates with holes through each plate. In contrast to previous solutions, the holes described herein are relatively large. For example, the holes may have diameters that are approximately 1.0 mm or greater, approximately 15 mm or greater, or approximately 25 mm or greater.

The larger holes will generally reduce the probability of the ions contacting the plates when the holes in the first plate are aligned with the holes in the second plate. Stated differently, when there is a high percentage of overlap between the holes, the ion flow rate to the substrate will be high. However, embodiments disclosed herein include plates that can be configured so that hole overlap is reduced. Depending on the desired amount of ion flow, the hole overlap between the first plate and the second plate can be between 0% and 100%.

In some embodiments, the ion blocking system is set to a desired overlap in order to process one or more substrates (e.g., with a dry etching process). Changes to the overlap percentage may be made manually between processing runs. In other embodiments, the ion blocking system may include one or more actuators that allow for automated changes to the overlap percentage. Such an embodiment may be beneficial for some etching processes. For example, a first portion of an etching process may need to be more aggressive (e.g., with a higher ion flow rate) than a second portion of the etching process (e.g., with a lower ion flow rate). Such a variable etching process may be particularly beneficial for the processing of three-dimensional (3D)-NAND structures.

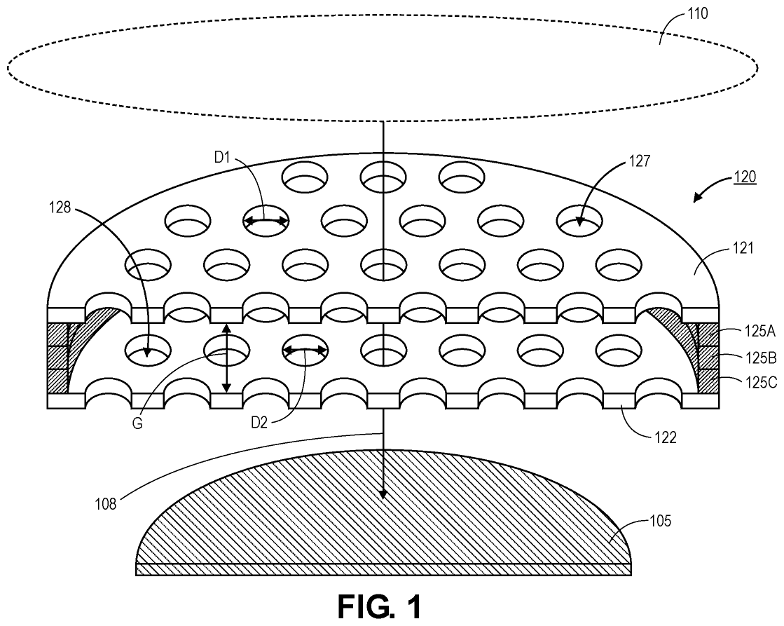

Referring now to FIG. 1, a perspective sectional view of an ion blocking system 120 is shown, in accordance with an embodiment. In an embodiment, the ion blocking system 120 may be useful as a shield between a plasma 110 and a substrate 105. As shown by the arrow 108, ions can pass from the plasma 110 through the ion blocking system 120 in order to reach a surface of the substrate 105.

In an embodiment, the ion blocking system 120 may comprise a first plate 121 and a second plate 122. The first plate 121 and the second plate 122 may be arranged in a stack. A spacer 125 may be provided between the first plate 121 and the second plate 122. In the illustrated embodiment, the spacer 125 comprises a plurality of shims 125A-125C in order to provide a desired gap G between the first plate 121 and the second plate 122. In other embodiments, a single shim 125A may be used for the spacer 125. The spacer 125 may comprise electrically conductive material or electrically insulating material. The gap G may be approximately 0.5 mm or greater, approximately 5.0 mm or greater, approximately 10 mm or greater, or approximately 20 mm or greater. Increasing the gap G may enable higher ion transmission. As used herein, “approximately” may refer to a range that is within ten percent of the stated value. For example, approximately 10 mm may refer to a range between 9 mm and 11 mm.

In an embodiment, the first plate 121 may comprise a plurality of first holes 127. The first holes 127 may be circular in some embodiments. Though, first holes 127 may have any shape. The first holes 127 pass entirely through a thickness of the first plate 121. In an embodiment, the first holes 127 may have a first diameter D1. The first diameter D1 may be approximately 1.0 mm or greater, approximately 15 mm or greater, or approximately 25 mm or greater. In an embodiment, the first diameter D1 may be equal to or greater than a thickness of the first plate 121.

In an embodiment, the second plate 122 may comprise a plurality of second holes 128. The second holes 128 may be circular in some embodiments. Though, second holes 128 may have any shape. The second holes 128 pass entirely through a thickness of the second plate 122. In an embodiment, the second holes 128 may have a second diameter D2. The second diameter D2 may be approximately 1.0 mm or greater, approximately 15 mm or greater, or approximately 25 mm or greater. In an embodiment, the second diameter D2 may be equal to or greater than a thickness of the second plate 122.

In an embodiment, the first plate 121 may be substantially similar to the second plate 121. For example, the first diameter D1 may be substantially equal to the second diameter D2. Additionally, placement of the first holes 127 may be aligned with the placement of the second holes 128. Though, as will be described in greater detail below, the first holes 127 may be different than the second holes 128. The first plate 121 and the second plate 122 may also comprise the same material or materials. In some embodiments, the first plate 121 and the second plate 122 may comprise one or more of alumina (Al₂O₃), aluminum nitride, or aluminum. In some embodiments, a metallic core may be covered with a coating, such as one comprising nickel or yttria.

In the configuration shown in FIG. 1, the first plate 121 and the second plate 122 are aligned so that the first holes 127 and the second holes 128 are aligned with each other. However, the flow rate of ions can be modulated by shifting one or both of the first plate 121 and the second plate 122 in order to offset the first holes 127 from the second holes 128. This shifting or displacement can be done manually or automatically (e.g., with actuators or the like).

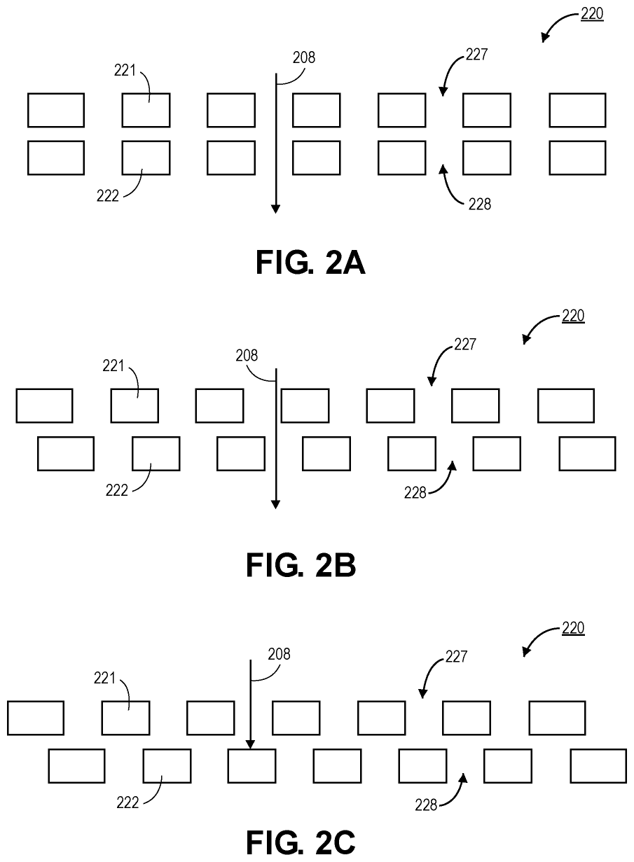

Referring now to FIGS. 2A-2C a series of cross-sectional illustrations depicting portions of ion blocking systems 220 in different configurations is shown, in accordance with an embodiment. In the illustrated embodiments, just the first plate 221 and the second plate 222 are shown for simplicity. However, embodiments may also include spacers, actuators, and/or other structures that may be described in greater detail herein.

Referring now to FIG. 2A, a cross-sectional illustration of an ion blocking system 220 is shown, in accordance with an embodiment. The ion blocking system 220 may include a first plate 221 that is provided over a second plate 222. The first plate 221 may comprise first holes 227, and the second plate 222 may comprise second holes 228. The first plate 221 may be aligned with the second plate 222 so that the first holes 227 and the second holes 228 completely overlap each other. In such a configuration, the maximum ion flow rate through the ion blocking system 220 is provided. For example, nearly all of the ions 208 that pass through the first holes 227 may all pass through the second holes 228.

Referring now to FIG. 2B, a cross-sectional illustration of an ion blocking system 220 in an alternative configuration is shown, in accordance with an embodiment. The ion blocking system 220 may include a first plate 221 that is provided over a second plate 222. The first plate 221 may comprise first holes 227, and the second plate 222 may comprise second holes 228. The first plate 221 may be offset from the second plate 222 so that the first holes 227 and the second holes 228 are not completely aligned with each other. For example, a centerline of a first hole 227 is offset from a centerline of a second hole 228 (that at least partially overlaps the first hole 227). The offset distance between the centerlines may be up to the diameter of the first hole 227 or the second hole 228.

In such a configuration, the ion flow rate through the ion blocking system 220 is reduced. The amount of the reduction in the ion flow rate (as compared to the configuration shown in FIG. 2A) can be between 0% and 100%, depending on the amount of offset. In some embodiments, the ion flow rate may be reduced between 25% and 75%. The reduction in the ion flow rate may be proportional to the reduction in overlapping area between the first hole 227 and the second hole 228. For example, changes in the ion flow rate may be directly correlated to changes in the overlapping area in a 1:1 relationship. In some instances some of the ions 208 passing through a first hole 227 may be blocked by the second plate 222, and some of the ions 208 passing through the first hole 227 may pass through a second hole 228.

Referring now to FIG. 2C, a cross-sectional a cross-sectional illustration of an ion blocking system 220 in an alternative configuration is shown, in accordance with an embodiment. The ion blocking system 220 may include a first plate 221 that is provided over a second plate 222. The first plate 221 may comprise first holes 227, and the second plate 222 may comprise second holes 228. The first plate 221 may be offset from the second plate 222 so that the first holes 227 do not overlap any portion of the second holes 228. In the configuration shown in FIG. 2C, the ion flow rate may be reduced to substantially 0% (compared to the configuration shown in FIG. 2A). That is, ions 208 that pass through the first holes 227 may be completely blocked by the second plate 222.

In the embodiments described with respect to FIGS. 2A-2C, the ions 208 are all illustrated as being oriented substantially orthogonally to the planar surfaces of the first plate 221 and the second plate 222. However, ions 208 may also pass through the ion blocking system 220 at other angles. Depending on the angle of the ion, different offsets of the holes 227 and 228 may result in different ion flow rates. For example, even when first holes 227 are completely offset from second holes 228 (e.g., as shown in FIG. 2C), ions 208 may still pass through the ion blocking system 220 when the ions 208 come at more extreme angles. Increasing spacing between holes, increasing the thickness of the plates 221 and/or 222, decreasing spacing between plates 221 and 222, and/or other structural changes may be used to reduce and/or eliminate leakage of ions 208 through the ion blocking system 220.

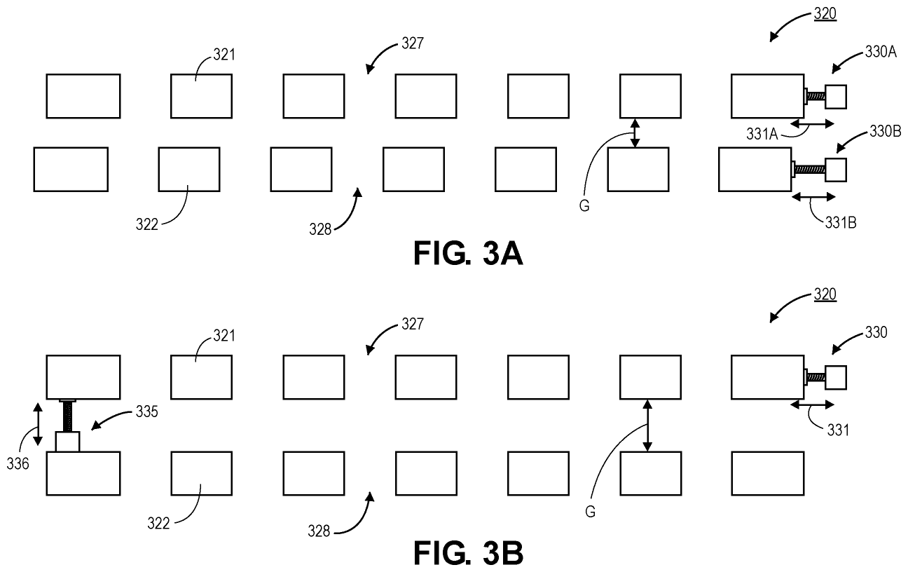

Referring now to FIG. 3A, a cross-sectional illustration of an ion blocking system 320 is shown, in accordance with an embodiment. In an embodiment, the ion blocking system 320 may comprise a first plate 321 with first holes 327 and a second plate 322 with second holes 328. In an embodiment, the first plate 321 may be spaced above the second plate 322 by a gap G. In an embodiment, the first plate 321 may be displaceable relative to the second plate 322. For example, arrows 331A and 331B indicate that the first plate 321 and the second plate 322 may be displaceable along planes that are substantially parallel to each other. The displacement may allow for a desired amount of overlap between the first holes 327 and the second holes 328. As such, the ion flow rate through the ion blocking system 320 can be controlled.

In an embodiment, the first plate 321 may be displaced by a first actuator 330A, and the second plate 322 may be displaced by a second actuator 330B. The first actuator 330A and the second actuator 330B may include any suitable actuating mechanism, such as an electromechanical actuator, a hydraulic actuator, pneumatic actuator, or a piezoelectric actuator. While each plate 321 and 322 is shown as having a single actuator 330, it is to be appreciated that a plurality of actuators 330 may be used to displace each plate 321 or 322. Further, while both plates 321 and 322 are shown as being displaceable by an actuator 330, in some embodiments only one of the plates 321 or 322 include an actuator. For example, the first plate 321 may be stationary, and the second plate 322 may be displaceable by one or more actuators 330.

The use of actuation allows for adjustment of the ion flow rate without the need for manually opening the chamber in which the ion blocking system 320 is housed. This is advantageous as it may allow for etching processes that include variable etching conditions. As will be described in greater detail herein, such a non-uniform etching process may be particularly beneficial for 3D-NAND fabrication processes.

Referring now to FIG. 3B, a cross-sectional illustration of an ion blocking system 320 is shown, in accordance with an additional embodiment. The ion blocking system 320 may be similar to the ion blocking system 320 in FIG. 3A, with the addition of a vertical actuator 335. In an embodiment, the vertical actuator 335 allows for the first plate 321 to be raised or lowered (as indicated by arrow 336) relative to the second plate 322. As such, the gap G between the first plate 321 and the second plate 322 can be modified in addition to changing first hole 327 and second hole 328 offsets (through the use of actuator 330). The actuator 335 may be any suitable actuator, such as an electromechanical actuator, a hydraulic actuator, pneumatic actuator, or a piezoelectric actuator.

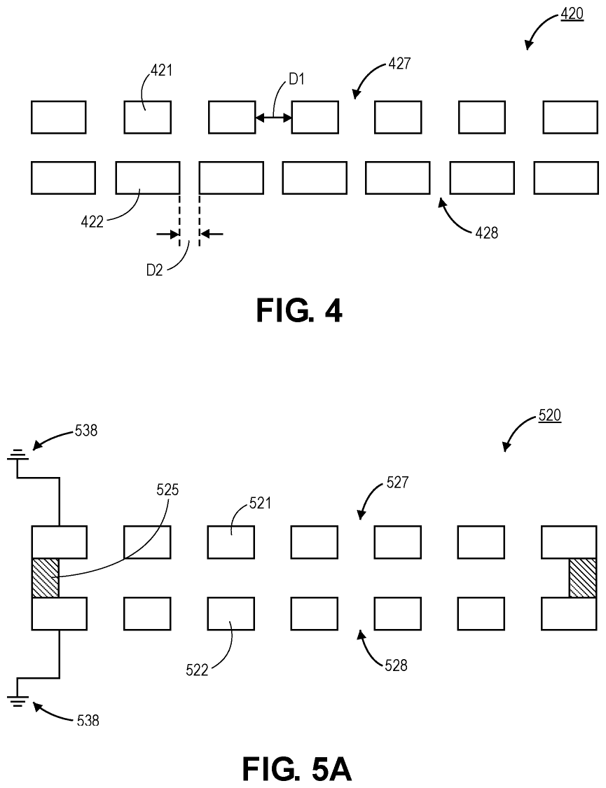

Referring now to FIG. 4, a cross-sectional illustration of an ion blocking system 420 is shown, in accordance with an additional embodiment. In an embodiment, the ion blocking system 420 may include a first plate 421 and a second plate 422. The first plate 421 may have first holes 427 with a first diameter D1, and the second plate 422 may have second holes 428 with a second diameter D2. The first diameter D1 may be different than the second diameter D2. For example, in FIG. 4, the second diameter D2 is smaller than the first diameter D1. Though, in other embodiments, the second diameter D2 may be larger the first diameter D1.

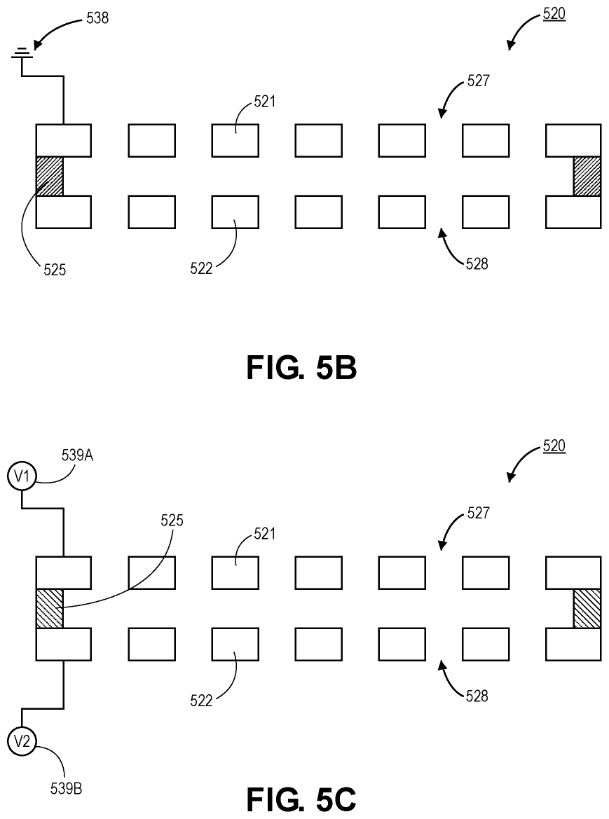

Referring now to FIGS. 5A-5C, a series of cross-sectional illustrations of various ion blocking systems 520 is shown, in accordance with an embodiment. In an embodiment, the ion blocking systems 520 in FIGS. 5A-5C may include different electrical configurations. For example, one or more of the plates 521 and/or 522 may be electrically grounded, electrically floating, or held at a certain voltage.

Referring now to FIG. 5A, a cross-sectional illustration of an ion blocking system 520 is shown, in accordance with an embodiment. In an embodiment, the ion blocking system 520 may comprise a first plate 521 with first holes 527 and a second plate 522 with second holes 528. The first plate 521 and the second plate 522 may be configured (either manually or through the use of actuators) so that the first holes 527 have an overlap with the second holes 528 in order to provide a desired ion flow rate through the ion blocking system 520.

In the illustrated embodiment, a spacer 525 is provided between the first plate 521 and the second plate 522. In some embodiments, the spacer 525 is an electrically insulating material, such as a ceramic, a polymer, or the like. As such, there may not be any electrical coupling between the first plate 521 and the second plate 522. Accordingly, both the first plate 521 and the second plate 522 may be electrically coupled to a ground 538.

Referring now to FIG. 5B, a cross-sectional illustration of an ion blocking system 520 is shown, in accordance with an additional embodiment. In an embodiment, the ion blocking system 520 in FIG. 5B may be similar to the ion blocking system 520 in FIG. 5A, with the exception of the spacer 525. Instead of being insulating, the spacer 525 may be electrically conducting. As such, the first plate 521 may be electrically coupled to the second plate 522 by the spacer 525. Accordingly, when it is desired that the ion blocking system 520 be grounded, only one of the plates 521 or 522 need to be electrically coupled to a ground 538. In the case shown in FIG. 5B, the first plate 521 is coupled to the ground 538.

Referring now to FIG. 5C, a cross-sectional illustration of an ion blocking system 520 is shown, in accordance with an additional embodiment. The ion blocking system 520 in FIG. 5C may be similar to the ion blocking system 520 in FIG. 5A, with the exception of the voltages to which the ion blocking system 520 is held. For example, the first plate 521 may be held to a first voltage 539A and the second plate 522 may be held to a second voltage 539B. The first voltage 539A may be different than the second voltage 539B. Additionally, while shown as being held to a particular voltage in FIG. 5C, one or both of the plates 521 and 522 may be electrically floating (i.e., not directly coupled to either a voltage potential or a ground potential).

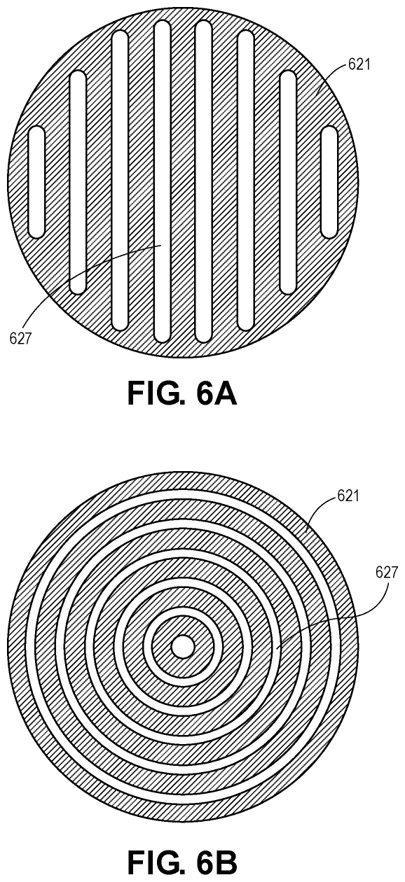

Referring now to FIGS. 6A and 6B, a pair of plan view illustrations of a plate 621 that can be used in an ion blocking system is shown, in accordance with an embodiment. The plate 621 may be similar to plates described in greater detail herein with the exception of the shape of the holes 627. In FIG. 6A, the holes 627 may be a series of slots that extend across the plate 621. The width and spacing of the holes 627 may be chosen in order to provide a desired ion flow rate. In FIG. 6B, the holes 627 may comprise a plurality of rings. In an embodiment, each ring may have a different inner and outer diameter. The spacing between holes 627 may be uniform or variable.

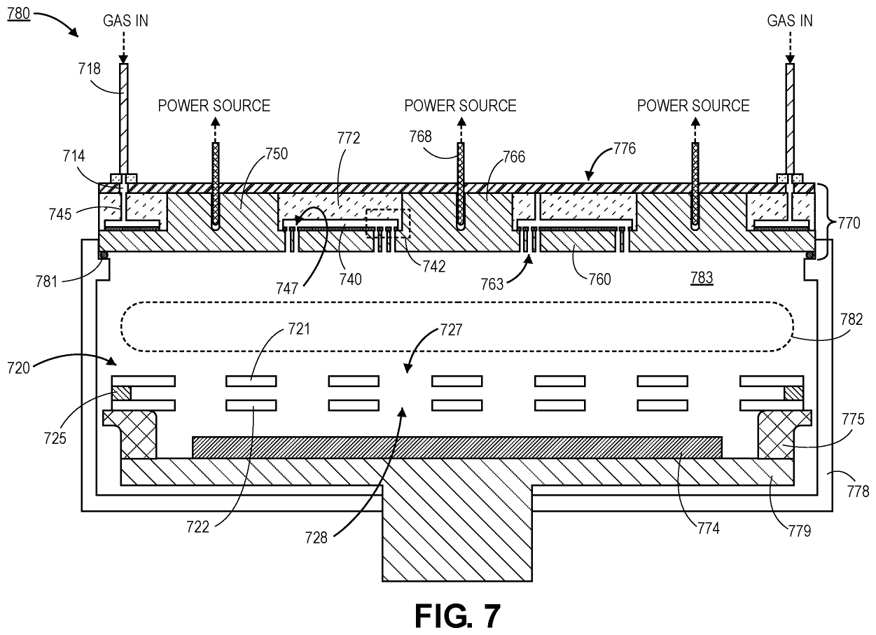

Referring now to FIG. 7, a cross-sectional illustration of a processing tool 780, e.g., a microwave plasma chamber, that includes an assembly 770 is shown, in accordance with one or more embodiments of the disclosure. It will be understood by the skilled artisan that while the disclosure refers to a microwave plasma chamber, any remote plasma source, inductively coupled plasma (ICP) source, capacitively coupled plasma source (CCP) source, or microwave plasma source may be implemented in the disclosed processes.

In some embodiments, the processing tool 780 comprises a processing chamber 778 that is sealed by the assembly 770. For example, the assembly 770 may rest against one or more O-rings 781 to provide a vacuum seal to an interior volume 783 of the processing chamber 778. In other embodiments, the assembly 770 interfaces with the processing chamber 778. Stated differently, in some embodiments, the assembly 770 may be part of a lid that seals the processing chamber 778. In some embodiments, a chuck 779, such as an electrostatic chuck, may support a workpiece 774 (e.g., wafer, substrate, etc.).

In some embodiments, the assembly 770 may comprise a monolithic source array 750, a housing 772, and a lid plate 776. The monolithic source array 750 may comprise a dielectric plate 760 and a plurality of protrusions 766 extending up from the dielectric plate 760. While a monolithic source array 750 is shown, it will be appreciated that the protrusions 766 may be distinct from the dielectric plate 760. The protrusions 766 may be isolated bodies that sit on top of the dielectric plate 760. In some embodiments, there may be five or more protrusions 766, or ten or more protrusions 766. In some embodiments, there are nineteen protrusions 766.

The protrusions 766 may include any suitable material known to the skilled artisan. In some embodiments, the protrusions 766 comprise a dielectric material. In some embodiments, the protrusions 766 function as dielectric resonators in order to couple microwaves into the chamber volume 783. In some embodiments, as used herein, the protrusions 766 may be referred to as “applicators,” or “plasma applicators,” or “microwave applicators.”

In some embodiments, the housing 772 includes openings sized to receive the protrusions 766. The housing 772 may be a conductive material. In some embodiments, the housing 772 is grounded. In the illustrated embodiment of FIG. 7, the housing 772 is directly supported by the dielectric plate 760, but it will also be appreciated that a thermal interface material or the like may separate the housing 772 from the dielectric plate 760. In some embodiments, monopole antennas 768 may extend into holes in the protrusions 266. In some embodiments, the holes in the protrusions 766 are larger than the monopole antennas 768 in order to allow for thermal expansion in order to prevent damage to the monolithic source array 750. In some embodiments, the monopole antennas 768 pass through a lid plate 776 over the housing 772 and the protrusions 766. In one or more embodiments, each of the monopole antennas 768 are coupled to different power sources. The skilled artisan will appreciate that the power sources can have any suitable construction.

The chamber volume 783 is suitable for striking a plasma 782. Stated differently, the chamber volume 783 may be a vacuum chamber. In some embodiments, a vacuum source may be fluidically coupled to the chamber volume 783. In order to strike the plasma 782, processing gasses may be flown into the chamber volume 783. The processing gasses may enter the assembly 770 via a gas line 718. The processing gas then passes through a hole 714 through the lid plate 776 and enters a hole 745 in the housing 772. The hole 745 intersects a gas distribution channel 740 that laterally distributes the processing gas. While shown as a plurality of discrete gas distribution channels 740, it will be appreciated by the skilled artisan that the gas distribution channels 740 are fluidically coupled to each other out of the plane of FIG. 7.

The processing gas exits the channel 740 through groups 742 of holes 747 in a cover over the channel 740. The processing gas then passes through gas distribution holes 763 through the dielectric plate 760 of the monolithic source array 750 and enters the chamber volume 783.

In an embodiment, an ion blocking system 720 is provided in the chamber 778 between the assembly 770 and the chuck 779. The ion blocking system 720 may be supported on a ledge 775 or any other internal support structure within the chamber 778 (e.g., edge ring, etc.). The ion blocking system 720 may be similar to any of the ion blocking systems described in greater detail herein. For example, the ion blocking system 720 may comprise a first plate 721 with first holes 727 and a second plate 722 with second holes 728. A spacer 725 may separate the first plate 721 from the second plate 722. The first plate 721 and the second plate 722 may be configured so that the first holes 727 and the second holes 728 have between 0% overlap and 100% overlap in order to control the ion flow rate through the ion blocking system 720. In an embodiment. The first plate 721 and the second plate 722 are set in their positions manually. In other embodiments, the first plate 721 and the second plate 722 are displaceable with respect to each other through the use of one or more actuators, such as those described in greater detail herein.

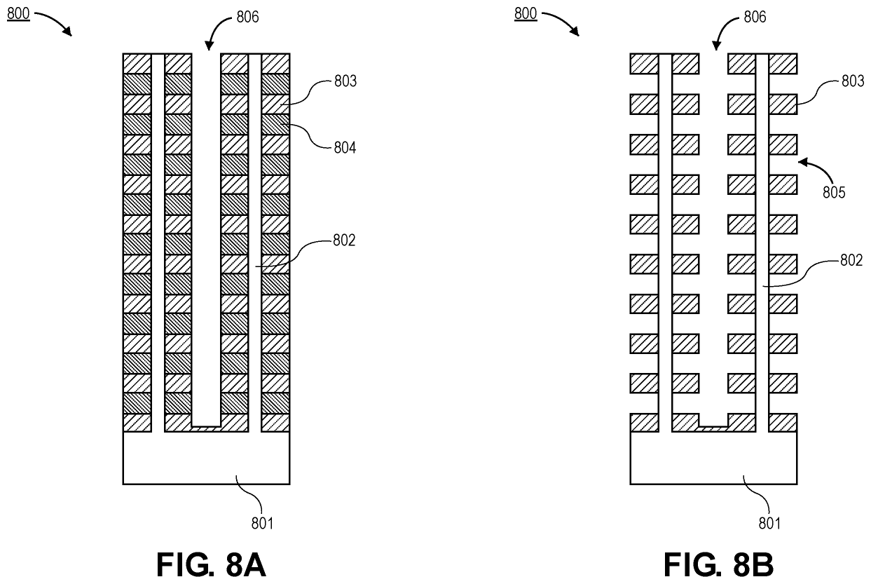

In some embodiments, an etching process with non-uniform processing conditions is desirable. For example, 3D-NAND architectures may benefit from such a process. In some instances, a first duration of the etching process may include an aggressive etch (e.g., with a high ion flow rate) in order to remove native oxide layers over the material to be etched, and a second duration of the etching process may include a less aggressive etch (e.g., with a lower ion flow rate) in order to protect the exposed oxide layer that is not desired to be etched. An example of such an etching process is shown in FIGS. 8A and 8B. FIG. 8A is a cross-sectional illustration of a portion of a 3D-NAND structure with alternating silicon oxide layers and silicon nitride layers. FIG. 8B is a cross-sectional illustration of a portion of the 3D-NAND structure of FIG. 8A after selectively etching the silicon nitride layers.

In one or more embodiments, the methods described herein are implemented on a 3D structure 800. For example, the 3D structure 800 may be a structure used for a 3D-NAND device. The 3D structure 800 includes a substrate 801, such as a polysilicon substrate, with polysilicon pillars 802 extending up from the substrate 801. In one or more embodiments, each pillar 802 is lined by alternating layers of silicon oxide (e.g., SiOₓ) 803 and silicon nitride (e.g., Si_{X}N_{Y}) 804. The sidewalls of the silicon nitride layers 804 and the silicon oxide layers 803 may be exposed by a trench 806 that passes through the layers between the pillars 802.

In some embodiments, the silicon nitride layers 804 are sacrificial layers. In embodiments where the silicon nitride layers 804 are sacrificial layers, the silicon nitride layers 804 are etched away, as shown in FIG. 8B. Initially, the etching process may include a high ion flow rate in order to remove any native oxides on the silicon nitride layers 804. After native oxides are removed, the ion flow rate may be reduced in order to minimize damage to the silicon oxide layers 803. The variable ion flow rate can be enabled through the use of an ion blocking system similar to any of the ion blocking systems described in greater detail herein. The removal of the silicon nitride layers 804 results in the formation of recesses 805 between the silicon oxide layers 803. In some embodiments, the recesses 805 are subsequently filled with a conductive layer (not shown) comprising any suitable conductive material known to the skilled artisan, such as tungsten (W).

Advantageously, embodiments of the present disclosure utilize etching chemistries that provide a high etch selectivity of the silicon nitride layers 804 relative to the silicon oxide layers 803. Embodiments of the present disclosure advantageously increase the etching rate of silicon nitride and thereby reduce the time needed to etch the silicon nitride layers 804. Embodiments of the present disclosure include using a plasma source, such as a modular microwave source, to generate a microwave plasma of a fluorine-containing precursor and a gas mixture as an etching chemistry, and using a plasma source, such as a modular microwave source, to generate a microwave plasma of a sulfur-containing precursor and a gas mixture as a passivating chemistry.

In FIGS. 8A and 8B, the structure 800 is shown as being suitable for a 3D-NAND device. The use of the etching processes described herein are particularly beneficial for use in 3D-NAND devices. It has advantageously found that the etching uniformity in highly scaled 3D-NAND devices, such as in structures with high aspect ratios and many silicon nitride layers 804 and silicon oxide layers 803, is substantially uniform at the top of the structure and the bottom of the structure. Additionally, the etching processes of one or more embodiments provides complete removal of the silicon nitride layers 804 without significantly damaging the silicon oxide layers 803. In some embodiments, the variable ion flow rate control in addition to use of sulfur-containing precursor/gas mixture chemistry that forms a passivation layer over the exposed portions of the silicon oxide layers 803 allows for improved protection of the silicon oxide layers 803. As used herein, the sulfur-containing precursor/gas mixture chemistry may be referred to as a “passivation chemistry.” In specific embodiments, the etching processes of one or more embodiments provides complete removal of the silicon nitride layers 804 without damaging the silicon oxide layers 803 having the passivation layer thereon.

It will be appreciated by the skilled artisan that embodiments of the present disclosure are not limited to the etching of 3D-NAND structures. For example, similar etching processes may be used wherever a silicon nitride structure needs to be etched selectively to a silicon oxide layer. For example, a silicon nitride layer may be provided over a silicon oxide layer, with the disclosed etching processes etching through the silicon nitride layer and stopping on the oxide layer. In such an embodiment, the silicon oxide layer may be considered an etch stop layer.

While examples of specific semiconductor device architectures that benefit from the use of a plasma source, such as a modular microwave source, to generate a microwave plasma of a fluorine-containing precursor and a gas mixture as an etching chemistry, and a microwave plasma of a sulfur-containing precursor and a gas mixture as a passivating chemistry, are provided, it will be appreciated by the skilled artisan that the provided examples are non-limiting, and there may be many different applications and architectures that benefit from the fluorine-containing precursor/gas mixture etching chemistry and sulfur-containing precursor/gas mixture passivating chemistry in accordance with one or more embodiments herein.

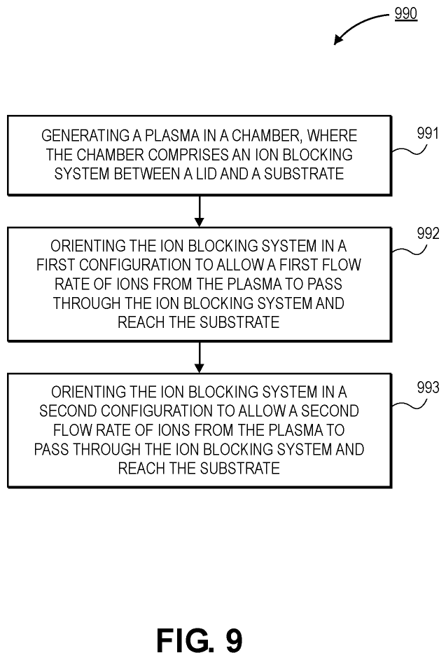

Referring now to FIG. 9, a process flow diagram of a process 990 for controlling an ion flow rate in a chamber is shown, in accordance with an embodiment. In the process 990, the chamber may be similar to any of the chambers and/or tools described in greater detail herein. Additionally, the ion blocking system may be similar to any of the ion blocking systems described in greater detail herein.

In an embodiment, the process 990 may begin with operation 991, which comprises generating a plasma in a chamber. In an embodiment, the chamber comprises an ion blocking system between a lid of the chamber and a substrate within the chamber. In an embodiment, the ion blocking system may include a first plate with first holes and a second plate with second holes. The plasma may be generated with any plasma source, such as a microwave plasma source, an ICP source, or a CCP source.

In an embodiment, the process 990 may continue with operation 992, which comprises orienting the ion blocking system in a first configuration to allow a first flow rate of ions from the plasma to pass through the ion blocking system and reach the substrate. In an embodiment, the first configuration may include an overlap between the first holes and the second holes that is up to approximately 100% of the area of the holes. In other embodiments, the first configuration may include overlaps that are at least 50%, or at least 75%. Though, smaller overlap percentages may also be used in some embodiments.

In an embodiment, the process 993 may continue with operation 993, which comprises orienting the ion blocking system in a second configuration to allow a second flow rate of ions from the plasma to pass through the ion blocking system and reach the substrate. In an embodiment, the second configuration may include an overlap percentage between the first holes and the second holes that is smaller than the overlap percentage in operation 992. In an embodiment, the overlap percentage of the second configuration may be up to 75% of the area of the holes. In other embodiments, the second configuration may include overlaps that are between 0% and 75%, or between 25% and 75%. Though, larger overlap percentages may also be used in some embodiments.

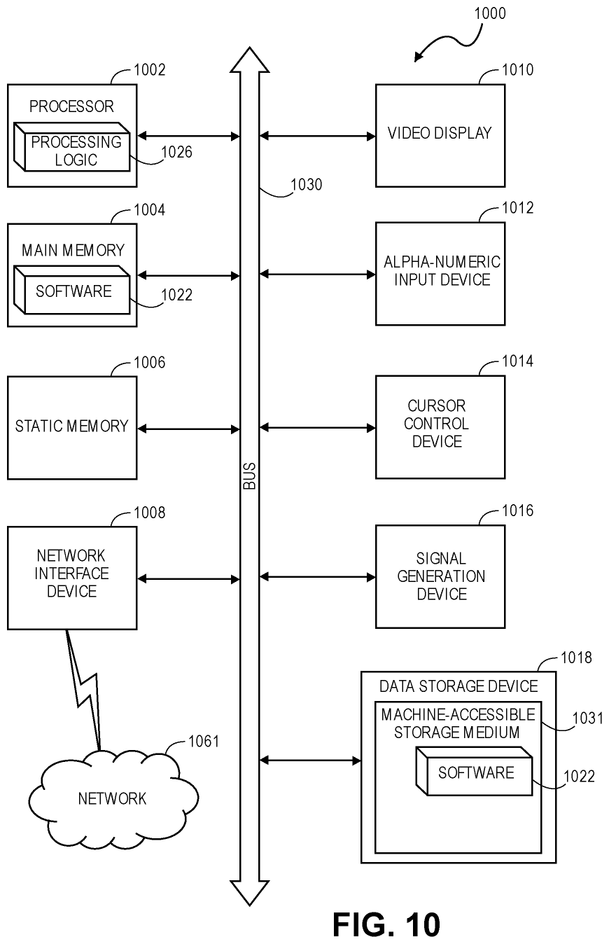

Referring now to FIG. 10, a block diagram of an exemplary computer system 1000 of a processing tool is illustrated in accordance with an embodiment. In an embodiment, computer system 1000 is coupled to and controls processing in the processing tool. Computer system 1000 may be connected (e.g., networked) to other machines in a Local Area Network (LAN), an intranet, an extranet, or the Internet. Computer system 1000 may operate in the capacity of a server or a client machine in a client-server network environment, or as a peer machine in a peer-to-peer (or distributed) network environment. Computer system 1000 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 1000, the term “machine” shall also be taken to include any collection of machines (e.g., computers) that individually or jointly execute a set (or multiple sets) of instructions to perform any one or more of the methodologies described herein.

Computer system 1000 may include a computer program product, or software 1022, having a non-transitory machine-readable medium having stored thereon instructions, which may be used to program computer system 1000 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 1000 includes a system processor 1002, a main memory 1004 (e.g., read-only memory (ROM), flash memory, dynamic random access memory (DRAM) such as synchronous DRAM (SDRAM) or Rambus DRAM (RDRAM), etc.), a static memory 1006 (e.g., flash memory, static random access memory (SRAM), etc.), and a secondary memory 1018 (e.g., a data storage device), which communicate with each other via a bus 1030.

System processor 1002 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 1002 may also be one or more special-purpose processing devices such as an application specific integrated circuit (ASIC), a field programmable gate array (FPGA), a digital signal system processor (DSP), network system processor, or the like. System processor 1002 is configured to execute the processing logic 1026 for performing the operations described herein.

The computer system 1000 may further include a system network interface device 1008 for communicating with other devices or machines. The computer system 1000 may also include a video display unit 1010 (e.g., a liquid crystal display (LCD), a light emitting diode display (LED), or a cathode ray tube (CRT)), an alphanumeric input device 1012 (e.g., a keyboard), a cursor control device 1014 (e.g., a mouse), and a signal generation device 1016 (e.g., a speaker).

The secondary memory 1018 may include a machine-accessible storage medium 1032 (or more specifically a computer-readable storage medium) on which is stored one or more sets of instructions (e.g., software 1022) embodying any one or more of the methodologies or functions described herein. The software 1022 may also reside, completely or at least partially, within the main memory 1004 and/or within the system processor 1002 during execution thereof by the computer system 1000, the main memory 1004 and the system processor 1002 also constituting machine-readable storage media. The software 1022 may further be transmitted or received over a network 1060 via the system network interface device 1008. In an embodiment, the network interface device 1008 may operate using RF coupling, optical coupling, acoustic coupling, or inductive coupling.

While the machine-accessible storage medium 1032 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An apparatus, comprising:
a first plate, wherein a plurality of first holes pass through a thickness of the first plate;
a second plate over the first plate, wherein a plurality of second holes pass through a thickness of the second plate; and
a spacer between the first plate and the second plate.

2. The apparatus of claim 1, further comprising:
an actuator coupled to the first plate, wherein the actuator is configured to displace the first plate along a plane that is substantially parallel to a top surface of the second plate.

3. The apparatus of claim 1, further comprising:
an actuator coupled to the first plate, wherein the actuator is configured to displace the first plate in order to change a gap between the first plate and the second plate.

4. The apparatus of claim 3, wherein the actuator is part of the spacer.

5. The apparatus of claim 1, wherein the first holes have a diameter that is equal to or greater than the thickness of the first plate.

6. The apparatus of claim 1, wherein the first holes have a diameter of approximately 1.0 cm or greater.

7. The apparatus of claim 1, wherein the first holes have a first diameter and the second holes have a second diameter that is substantially equal to the first diameter.

8. The apparatus of claim 1, wherein the spacer is electrically insulating.

9. The apparatus of claim 8, wherein the first plate is configured to be held at a first voltage, and wherein the second plate is configured to be held at a second voltage that is different than the first voltage.

10. The apparatus of claim 1, wherein the first plate and the second plate comprise one or more of alumina, aluminum nitride, or aluminum.

11. The apparatus of claim 10, wherein a coating is provided over the first plate and the second plate, and wherein the coating comprises nickel or yttria.

12. A method for plasma etching, comprising:
generating a plasma in a chamber, where the chamber comprises an ion blocking system between a lid of the chamber and a substrate;
orienting the ion blocking system in a first configuration to allow a first flow rate of ions from the plasma to pass through the ion blocking system and reach the substrate; and
orienting the ion blocking system in a second configuration to allow a second flow rate of ions from the plasma to pass through the ion blocking system and reach the substrate.

13. The method of claim 12, wherein the ion blocking system comprises:
a first plate, wherein a plurality of first holes pass through a thickness of the first plate; and
a second plate over the first plate, wherein a plurality of second holes pass through a thickness of the second plate.

14. The method of claim 13, wherein the first configuration includes aligning the plurality of first holes with the plurality of second holes to allow for at least 75% overlapping area between the first holes and the second holes, and wherein the second configuration includes aligning the plurality of first holes with the plurality of second holes so that there is less than 75% overlapping area between the first holes and the second holes.

15. The method of claim 12, wherein the first flow rate of ions is higher than the second flow rate of ions.

16. The method of claim 12, wherein the plasma is generated with a microwave plasma source.

17. The method of claim 12, wherein the plasma etching is an operation in the formation of three-dimensional (3D)-NAND devices on the substrate.

18. A tool, comprising:
a chamber;
a plasma source coupled to the chamber;
a pedestal for supporting a substrate in the chamber; and
an ion blocking system between the pedestal and the plasma source, wherein the ion blocking system comprises:
a first plate, wherein a plurality of first holes pass through a thickness of the first plate; and
a second plate over the first plate, wherein a plurality of second holes pass through a thickness of the second plate.

19. The tool of claim 18, wherein the plasma source comprises a microwave plasma source, an inductively coupled plasma (ICP) source, or a capacitively coupled plasma (CCP) source.

20. The tool of claim 18, wherein the first plate and the second plate are displaceable relative to each other.
